(19) United States
(12) Patent Application Publication
(10) Pub. No.: US 2014/0374729 A1
(43) Pub. Date: Dec. 25, 2014

(54) METHOD FOR PRODUCING AN OPTOELECTRONIC COMPONENT, AND OPTOELECTRONIC COMPONENT

(71) Applicant: OSRAM Opto Semiconductors GmbH, Regensburg (DE)

(72) Inventors: Thomas Dobbertin, Regensburg (DE); Benjamin Krummacher, Regensburg (DE); Thilo Reusch, Regensburg (DE); Simon Schicktanz, Regensburg (DE); Stefan Seidel, Wenzenbach (DE); Daniel Steffen Setz, Muenchen (DE); Thomas Wehlus, Lappersdorf (DE)

(73) Assignee: OSRAM Opto Semiconductors GmbH, Regenburg (DE)

(21) Appl. No.: 14/375,802

(22) PCT Filed: Jan. 31, 2013
(86) PCT No.: PCT/EP2013/051839

§ 371 Date: Jul. 31, 2014

(30) Foreign Application Priority Data
Feb. 1, 2012 (DE) 102012201457.8

(51) Int. Cl. H01L 51/00; H01L 51/42; H01L 51/50

(52) U.S. Cl. CPC H01L 51/0014; H01L 51/0096; H01L 51/50; H01L 51/42
USPC 257/40; 438/99

(57) ABSTRACT

Various embodiments relate to a method for producing an optoelectronic component includes applying a planarization medium to a surface of a substrate, wherein the planarization medium comprises a material which absorbs electromagnetic radiation having wavelengths of a maximum of 600 nm, applying a first electrode on or above the material, forming an organic functional layer structure on or above the first electrode, and forming a second electrode on or above the organic functional layer structure.

### RELATED APPLICATIONS

The present application is a national stage entry according to 35 U.S.C. §371 of PCT application No.: PCT/EP2013/051839 filed on Jan. 31, 2013, which claims priority from German application No.: 10 2012 201 457.8 filed on Feb. 1, 2012, and is incorporated herein by reference in its entirety.

### TECHNICAL FIELD

Various embodiments relate to a method for producing an optoelectronic component, and to an optoelectronic component.

### BACKGROUND

The materials of optoelectronic components, for example of organic light-emitting diodes, incur damage in the event of excessively high ultraviolet (UV) irradiation, which adversely affects the performance data. This includes, for example, an increased operating voltage or a reduction of the current efficiency or of the quantum efficiency through to failure of the light emission. These can concern the entire active area or else occur locally. Furthermore, the organic materials can be damaged to an extent such that in places light emission or conversion no longer occurs and the active luminous area of the optoelectronic component is thus reduced.

The UV absorption of the soda lime flat glasses usually used (so-called soda lime float glass) is insufficient for preventing damage to an organic light-emitting diode (OLED). Although soda lime float glass has sufficient absorption below 300 nm, it is partly transmissive precisely in a range of 300 nm to 400 nm (this substantially corresponds to the wavelength range of UV-A radiation).

In general, it is possible to apply additional UV-absorbing films/layers on the outer side of the substrate of an OLED. However, this has the disadvantage that the high-quality glass surface usually used cannot be obtained and the OLED is additionally more susceptible to scratching.

It is furthermore alternatively possible to integrate UV-absorbing properties into the substrate glass, for example by altering the glass formulation. However, this solution is associated with comparatively high complexity and generally alters numerous other properties of the glass of an OLED. In particular, such glasses are more expensive than the soda lime float glasses usually used.

DE 696 32 227 T2 describes an electrochromic device in which at least one transparent electrically conductive plate is provided with a UV-absorbing layer, wherein the UV-absorbing layer is arranged between a transparent substrate and a transparent electrode. The UV-absorbing layer contains an organic UV absorber and can substantially consist of a UV absorber alone or of an organic UV absorber and a base layer. The thickness of the UV-absorbing layer is 10 nm to 100 μm.

Usually, in order to apply a UV absorber to a substrate, the substrate is planarized and then the UV absorber embedded into a matrix material is applied to the planarized substrate.

However, this planarization step is complex and expensive.

### SUMMARY

The present disclosure addresses the problem of providing a method for producing an optoelectronic component and an optoelectronic component which can be carried out and produced more cost-effectively.

Various embodiments provide a method for producing an optoelectronic component and an optoelectronic component.

Various embodiments provide a UV protection of an optoelectronic component, for example of an active optoelectronic component, for example of a light-emitting component, for example of an OLED, while simultaneously obtaining a high-grade substrate surface, for example a glass surface, for example an outer side of the substrate surface, for example the glass surface, of an optoelectronic component.

A method for producing an optoelectronic component may include applying a planarization medium to a surface of a substrate, for example to an inner side of the substrate (for example to an inner side of a substrate surface, for example of the glass surface, of an optoelectronic component, wherein the planarization medium includes a material (also designated hereinafter as radiation-absorbing material) which absorbs electromagnetic radiation having wavelengths of a maximum of 600 nm; applying a first electrode on or above the material; forming an organic functional layer structure on or above the first electrode; and forming a second electrode on or above the organic functional layer structure.

In accordance with this method, an additional step of planarizing the substrate surface can be dispensed with, since the radiation-absorbing material is applied to the surface of the substrate jointly (to put it another way as part of the planarization medium) with the planarization medium. Consequently, this method can be carried out more cost-effectively. This method likewise affords the possibility of using more favorable substrates with less stringent requirements made of the surface quality (e.g. flat glass or window glass).

In one configuration, the material can be designed in such a way that it absorbs radiation having wavelengths of a maximum of 575 nm, for example of a maximum of 550 nm, for example of a maximum of 525 nm, for example of a maximum of 500 nm, for example of a maximum of 475 nm, for example of a maximum of 450 nm, for example of a maximum of 425 nm, for example of a maximum of 400 nm. Consequently, the material can be designed in such a way that radiation having wavelengths in a range of ultraviolet (UV) radiation or else radiation having wavelengths in a range of blue light is absorbed, whereby it becomes possible to protect the optoelectronic component efficiently against such a respective radiation. In another configuration, the material can be designed in such a way that it absorbs radiation having wavelengths in a range of approximately 300 nm to approximately 400 nm (this substantially corresponds to the wavelength range of UV-A radiation).

In another configuration, the planarization medium can be applied with a thickness such that a percentage of the electromagnetic radiation is absorbed in a range of approximately 85% to approximately 99%, for example in a range of approximately 87% to approximately 98%, for example in a range of approximately 89% to approximately 97%, for example in a range of approximately 91% to approximately 96%. In one configuration, the planarization medium can be applied with a thickness such that a percentage of the electromagnetic radiation is absorbed of at least 85%, for example of at least 87%, for example of at least 89%, for example of at least 91%, for example of at least 93%, for example of at least 95%, for example of at least 97%, for example of at least 99%. In another configuration, the material can be designed and the planarization medium can be applied with a thickness such that the above-described percentages of the electromagnetic radiation are absorbed in the wavelength ranges mentioned above.

In another configuration, the material which absorbs radiation having wavelengths of a maximum of 600 nm can be admixed with a carrier material, such that the planarization medium is formed; and after admixing the material, the planarization medium can be applied to the surface of the substrate. This configuration enables simple and thus cost-effective application of the radiation-absorbing material, jointly with a carrier material, for example a matrix material, into which the radiation-absorbing material is embedded.

In another configuration, the planarization medium can be applied to the surface of the substrate by means of one of the following methods: spin coating, blade coating, printing, spraying, spreading, rolling, drawing, wiping, dipping, flooding, slot casting. In another configuration, the planarization medium can be applied by means of a contact-free method. The many different possibilities for applying the planarization medium and thus the radiation-absorbing material to the surface of the substrate lead to flexible and diversely usable processes.

In another configuration, the planarization medium can be a liquid, and after applying the planarization medium, the planarization medium can be cured. If the planarization medium is in the liquid phase, it can be processed and applied to the surface of the substrate very simply and cost-effectively.

In another configuration, curing can include at least one of the following methods: outdiffusion of a solvent contained in the planarization medium (the solvent is a different material than the radiation-absorbing material); irradiation of the planarization medium with electromagnetic radiation, for example with one or a plurality of electron beams; and/or heating of the planarization medium; and/or polymerization by air moisture; and/or reaction of two constituents of the planarization medium such as in the case of a two-component lacquer, for example.

In another configuration, the planarization medium can include a polymer to which the material which absorbs radiation having wavelengths of a maximum of 600 nm is bonded as molecule radical.

In another configuration, the optoelectronic component can include or be a light-emitting component and/or a solar cell.

In another configuration, the planarization medium can have a roughness of a maximum of 0.25 μm, for example of a maximum of 0.24 μm, for example of a maximum of 0.23 μm, for example of a maximum of 0.22 μm, for example of a maximum of 0.21 μm, for example of a maximum of 0.20 μm, for example of a maximum of 0.19 μm, for example of a maximum of 0.19 μm, for example of a maximum of 0.18 μm, for example of a maximum of 0.17 μm, for example of a maximum of 0.16 μm, for example of a maximum of 0.15 μm, for example of a maximum of 0.13 μm, for example of a maximum of 0.11 μm, for example of a maximum of 0.10 μm, for example of a maximum of 0.05 μm.

Various embodiments provide an optoelectronic component, including a substrate; a planarization medium applied on a surface of the substrate, wherein the planarization medium includes a material which absorbs radiation having wavelengths of a maximum of 600 nm; a first electrode on or above the material; an organic functional layer structure on or above the first electrode; and a second electrode on or above the organic functional layer structure.

In one configuration, the planarization medium and/or the material can have a thickness such that a percentage of the electromagnetic radiation is absorbed in a range of approximately 85% to approximately 99%, for example in a range of approximately 87% to approximately 98%, for example in a range of approximately 89% to approximately 97%, for example in a range of approximately 91% to approximately 96%. In one configuration, the planarization medium can be applied with a thickness such that a percentage of the electromagnetic radiation is absorbed of at least 85%, for example of at least 87%, for example of at least 89%, for example of at least 91%, for example of at least 93%, for example of at least 95%, for example of at least 97%, for example of at least 99%. In another configuration, the material can be designed and the planarization medium can be applied with a thickness such that the above-described percentages of the electromagnetic radiation are absorbed in the wavelength ranges mentioned above.

In another configuration, the planarization medium can include a polymer to which the material which absorbs radiation having wavelengths of a maximum of 600 nm is bonded as molecule radical.

In another configuration, the material can be designed in such a way that it absorbs radiation having wavelengths of a maximum of 575 nm, for example of a maximum of 550 nm, for example of a maximum of 525 nm, for example of a maximum of 500 nm, for example of a maximum of 475 nm, for example of a maximum of 450 nm, for example of a maximum of 425 nm, for example of a maximum of 400 nm. Consequently, the material can be designed in such a way that radiation having wavelengths in the range of ultraviolet (UV) radiation or else radiation having wavelengths in the range of blue light is absorbed, whereby it becomes possible to protect the optoelectronic component efficiently against such a radiation.

In another configuration, the optoelectronic component can include or be a light-emitting component and/or a solar cell.

In another configuration, the planarization medium can have a roughness of a maximum of 0.25 μm, for example of a maximum of 0.24 μm, for example of a maximum of 0.23 μm, for example of a maximum of 0.22 μm, for example of a maximum of 0.21 μm, for example of a maximum of 0.20 μm, for example of a maximum of 0.19 μm, for example of a maximum of 0.19 μm, for example of a maximum of 0.18 μm, for example of a maximum of 0.17 μm, for example of a maximum of 0.16 μm, for example of a maximum of 0.15 μm, for example of a maximum of 0.13 μm, for example of a maximum of 0.11 μm, for example of a maximum of 0.10 μm, for example of a maximum of 0.05 μm.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a cross-sectional view of an optoelectronic component at a first point in time of its production in accordance with various embodiments;

FIG. 2 shows a cross-sectional view of an optoelectronic component at a second point in time of its production in accordance with various embodiments;

FIG. 3 shows a cross-sectional view of an optoelectronic component in accordance with various embodiments; and

FIG. 4 shows a cross-sectional view of an optoelectronic component in accordance with various embodiments.

### DETAILED DESCRIPTION

In the following detailed description, reference is made to the accompanying drawings, which form part of this description and show for illustration purposes specific embodiments in which the disclosure can be implemented. In this regard, direction terminology such as, for instance, “at the top”, “at the bottom”, “at the front”, “at the back”, “front”, “rear”, etc. is used with respect to the orientation of the figure(s) described. Since component parts of embodiments can be positioned in a number of different orientations, the direction terminology serves for illustration and is not restrictive in any way whatsoever. It goes without saying that other embodiments can be used and structural or logical changes can be made, without departing from the scope of protection of the present disclosure. It goes without saying that the features of the various embodiments described herein can be combined with one another, unless specifically indicated otherwise. Therefore, the following detailed description should not be interpreted in a restrictive sense, and the scope of protection of the present disclosureis defined by the appended claims.

In the context of this description, the terms “connected” and “coupled” are used to describe both a direct and an indirect connection and a direct or indirect coupling. In the figures, identical or similar elements are provided with identical reference signs, insofar as this is expedient.

In various embodiments, a description is given of an integrated process for improving the UV resistance while at the same time obtaining a high-quality off-state appearance for an optoelectronic component.

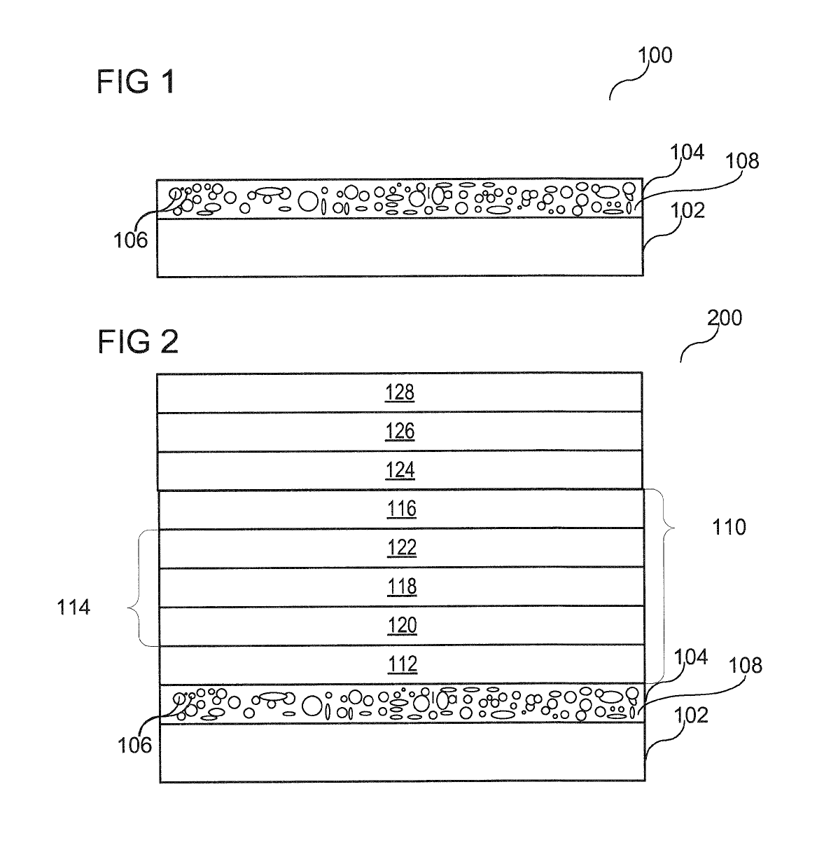

FIG. 1 shows a first cross-sectional view of an optoelectronic component 100 at a first point in time of its production in accordance with various embodiments.

Even though various embodiments of a light-emitting component, implemented in the form of an organic light-emitting diode (OLED), are described below, it should be pointed out that these embodiments can correspondingly also be used for a different optoelectronic component, for example for a solar cell. Furthermore, in various embodiments, a light-emitting component can be embodied as an organic light-emitting transistor. In various embodiments, the light-emitting component can be part of an integrated circuit. Furthermore, a plurality of light-emitting components can be provided, for example in a manner accommodated in a common housing.

The light-emitting component 100 in the form of an organic light-emitting diode 100 can have a substrate 102. The substrate 102 can serve for example as a carrier element for electronic elements or layers, for example light-emitting elements. By way of example, the substrate 102 can include or be formed from glass, quartz, and/or a semiconductor material or any other suitable material. Furthermore, the substrate 102 can include or be formed from a plastic film or a laminate including one or including a plurality of plastic films. The plastic can include or be formed from one or more polyolefins (for example high or low density polyethylene (PE) or polypropylene (PP)). Furthermore, the plastic can include or be formed from polyvinyl chloride (PVC), polystyrene (PS), polyester and/or polycarbonate (PC), polyethylene terephthalate (PET), polyether sulfone (PES) and/or polyethylene naphthalate (PEN). The substrate 102 can include one or more of the materials mentioned above. The substrate 102 can be embodied as translucent or even transparent.

In various embodiments, the term “translucent” or “translucent layer” can be understood to mean that a layer is transmissive to light, for example to the light generated by the light-emitting component, for example in one or more wavelength ranges, for example to light in a wavelength range of visible light (for example at least in a partial range of the wavelength range of from 380 nm to 780 nm). By way of example, in various embodiments, the term “translucent layer” should be understood to mean that substantially the entire quantity of light coupled into a structure (for example a layer) is also coupled out from the structure (for example layer), wherein part of the light can be scattered in this case.

In various embodiments, the term “transparent” or “transparent layer” can be understood to mean that a layer is transmissive to light (for example at least in a partial range of the wavelength range of from 380 nm to 780 nm), wherein light coupled into a structure (for example a layer) is also coupled out from the structure (for example layer) substantially without scattering or light conversion. Consequently, in various embodiments, “transparent” should be regarded as a special case of “translucent”.

For the case where, for example, a light-emitting monochromatic or emission spectrum-limited electronic component is intended to be provided, it suffices for the optically translucent layer structure to be translucent at least in a partial range of the wavelength range of the desired monochromatic light or for the limited emission spectrum.

In various embodiments, the organic light-emitting diode 100 (or else the light-emitting components in accordance with the embodiments that have been described above or will be described below) can be designed as a so-called top and bottom emitter. A top and bottom emitter can also be designated as an optically transparent component, for example a transparent organic light-emitting diode.

In various embodiments, a barrier layer (not illustrated) can optionally be arranged on or above the substrate 102. The barrier layer can include or consist of one or more of the following materials: aluminum oxide, zinc oxide, zirconium oxide, titanium oxide, hafnium oxide, tantalum oxide lanthanum oxide, silicon oxide, silicon nitride, silicon oxynitride, indium tin oxide, indium zinc oxide, aluminum-doped zinc oxide, and mixtures and alloys thereof. Furthermore, in various embodiments, the barrier layer can have a layer thickness in a range of approximately 0.1 nm (one atomic layer) to approximately 5000 nm, for example a layer thickness in a range of approximately 10 nm to approximately 200 nm, for example a layer thickness of approximately 40 nm.

Furthermore, in various embodiments, a planarization medium 104 can be applied on an upper surface of the substrate 102 or, if appropriate, of the exposed surface of the barrier layer.

The planarization medium 104 can include a material 106 which absorbs radiation having wavelengths of a maximum of 600 nm. The material 106 can be designed in such a way that it absorbs radiation having wavelengths of a maximum of 575 nm, for example of a maximum of 550 nm, for example of a maximum of 525 nm, for example of a maximum of 500 nm, for example of a maximum of 475 nm, for example of a maximum of 450 nm, for example of a maximum of 425 nm, for example of a maximum of 400 nm. Consequently, illustratively the material 106 can be designed in such a way that it absorbs radiation having wavelengths in the range of ultraviolet (UV) radiation or else radiation having wavelengths in the range of blue light.

The material 106 can be an organic UV absorber material, for example. In various embodiments, the UV absorber material can include a benzotriazole structure or a benzophenone structure. An organic UV absorber material including a benzotriazole structure can include, for example, 2-(2′-hydroxy-3′,5′-methylphenyl)benzotriazole, 2-(2′-hydroxy-3′,5′-bis(α,α-dimethylbenzyl)phenyl)benzotriazole, 2-(2′-hydroxy-3′,5′-di-t-butylphenyl)benzotriazole, 2-(2′-hydroxy-3′-t-butyl-5′-methylphenyl)-5-chlorobenzo-triazole and 3-(5-chloro-2H-benzotriazol-2-yl)-5-(1,1-dimethylethyl)-4-hydroxybenzenepropanoic acid octyl ester. An organic UV absorber material having a benzophenone structure can include 2,4-dihydroxybenzophenone, 2-hydroxy-4-methoxybenzophenone, 2-hydroxy-4-methoxybenzophenone-5-sulfonic acid, 2-hydroxy-4-n-octoxybenzophenone, 2,2′-dihydroxy-4,4′-dimethoxybenzophenone, 2,2′,4,4′-tetrahydroxy-benzophenone and 2-hydroxy-4-methoxy-2′-carboxybenzophenone. These UV absorber materials can be used by themselves or as a mixture. Other suitable UV absorber materials can be used in alternative embodiments.

The material 106 can be embedded in a carrier material 108, for example a matrix material 108, or can be admixed with the carrier material 108. In various embodiments, the matrix material can include one or more of the following materials: epoxy resin, glass solder, acrylate (for example polymethyl methacrylate), all possible polymers (for example polycarbonate, polyethylene naphthalate, polyethylene terephthalate, polyurethane). Titanium dioxide, silicon nitride, aluminum oxide.

Illustratively, in various embodiments, the matrix material 108 and the absorber material 106 embedded therein form the planarization medium 104.

In various embodiments, the planarization medium 104 can be present in the liquid phase or in the gas phase and can be applied to the surface of the substrate 102 in the liquid phase or in the gas phase. If the planarization medium 104 is present in the liquid phase, then it can be applied (for example after the absorber material 106 has been admixed with the carrier material 108) to the surface of the substrate by means of one of the following methods: spin coating, blade coating, printing, spraying, spreading, rolling, drawing, wiping, dipping, flooding, slot casting. In another configuration, the planarization medium can be applied by means of a contact-free method. The many different possibilities for applying the planarization medium and thus the radiation-absorbing material to the surface of the substrate lead to flexible and diversely usable processes.

The planarization medium 104 can subsequently be cured, for example by means of outdiffusion of a solvent contained in the planarization medium. In various embodiments, one or more of the following solvents can be used: acetone, acetonitrile, aniline, anisole, benzene, benzonitrile, bromobenzene, 1-butanol, tert-butyl methyl ether (TBME), γ-butyrolactone, quinoline, chlorobenzene, chloroform, cyclohexane, diethylene glycol, diethyl ether, dimethylacetamide, dimethylformamide, dimethyl sulfoxide, 1,4-dioxane, glacial acetic acid, acetic anhydride, ethyl acetate, ethanol, ethylene dichloride, ethylene glycol, ethylene glycol dimethyl ether, formamide, n-hexane, n-heptane, 2-propanol (isopropyl alcohol), methanol, 3-methyl-1-butanol (isoamyl alcohol), 2-methyl-2-propanol (tert-butanol), methylene chloride, methyl ethyl ketone (butanone), N-methyl-2-pyrrolidone (NMP), N-methylformamide, nitrobenzene, nitromethane, n-pentane, petroleum ether/light benzine, piperidine, propanol, propylene carbonate (4-methyl-1,3-dioxol-2-one), pyridine, carbon disulfide, sulfolane, tetrachloroethene, carbon tetrachloride, tetrahydrofuran, toluene, 1,1,1-trichloroethane, trichloroethene, triethylamine, triethylene glycol, triethylene glycol dimethyl ether (triglyme), for example water, ethanol, butanol, n-propanol, isopropanol, ethanol, mesitylene, phenetol, anisole, toluene, PGDA, generally glycol ether, methyl ethyl ketone, chlorobenzene, diethyl ether, ethyl acetate. Alternatively, the still liquid planarization medium 104 can be irradiated with light and thus cured optically. As a further alternative, the still liquid planarization medium 104 can be cured by means of temperature activation.

Alternatively, the material 106 can include a polymer to which the material which absorbs radiation having wavelengths of a maximum of 600 nm is bonded as molecule radical. In this case, a polymer can be applied directly to the surface of the substrate 102 in a simple and cost-effective manner.

In various embodiments, the planarization medium 104 can be applied with a thickness such that a percentage of the light is absorbed in a range of approximately 85% to approximately 99%. Furthermore, the planarization medium 104 can have a roughness of a maximum of 0.25 μm.

In various embodiments, by way of example, during a wet-chemical deposition of the planarization medium 104 onto the substrate 102, light-scattering particles can additionally also be introduced or embedded in the planarization medium 104, which particles can lead to a further improvement in the color angle distortion and the coupling-out efficiency. In this case, the light scattering is brought about by a difference in refractive index between the planarization medium and the particle or particles. In various embodiments, the light-scattering particles provided can be dielectric scattering particles, for example, such as metal oxides, for example, such as, for example, silicon oxide (SiO₂), zinc oxide (ZnO), zirconium oxide (ZrO₂), indium tin oxide (ITO) or indium zinc oxide (IZO), gallium oxide (Ga₂Oₐ, for example where a=1 or 3), aluminum oxide, or titanium oxide. Other particles may also be suitable, for example air bubbles, acrylate, or hollow glass beads. Furthermore, by way of example, metallic nanoparticles, metals such as gold, silver, iron nanoparticles, or the like can be provided as light-scattering particles.

It should be noted that the thickness of the planarization medium 104 is dependent on the roughness of the surface 106 to be planarized of the substrate 102 and the desired roughness of the exposed surface of the planarization medium 104 or of the material 106.

Illustratively, the use of the planarization medium 104 and of the material 106 thus results in a planarization of the surface of the substrate 102 and at the same time radiation protection of the optoelectronic component during irradiation by, for example, UV radiation from the substrate side.

FIG. 2 shows a second cross-sectional view of an optoelectronic component 200 at a second point in time of its production in accordance with various embodiments.

An electrically active region 110 of the light-emitting component 200 can be arranged on or above the planarization medium 104 (or for example on or above the material 106 if, for example, only the material 106 remains after curing). The electrically active region 110 can be understood as that region of the light-emitting component 200 in which an electric current for the operation of the light-emitting component 200 flows. In various embodiments, the electrically active region 110 can have a first electrode 112, a second electrode 116 and an organic functional layer structure 114, as will be explained in even greater detail below.

In this regard, in various embodiments, the first electrode 112 (for example in the form of a first electrode layer 112) can be applied on or above the planarization medium 104. The first electrode 112 (also designated hereinafter as bottom electrode 112) can be formed from an electrically conductive material, such as, for example, a metal or a transparent conductive oxide (TCO) or a layer stack including a plurality of layers of the same metal or different metals and/or the same TCO or different TCOs. Transparent conductive oxides are transparent conductive materials, for example metal oxides, such as, for example, zinc oxide, tin oxide, cadmium oxide, titanium oxide, indium oxide, or indium tin oxide (ITO). Alongside binary metal-oxygen compounds, such as, for example, ZnO, SnO₂, or In₂O₂, ternary metal-oxygen compounds, such as, for example, AlZnO, Zn₂SnO₄, CdSnO₂, ZnSnO₂, MgIn₂O₄, GaInO₂, Zn₂In₂O₅ or In₄Sn₃O₁₂, or mixtures of different transparent conductive oxides also belong to the group of TCOs and can be used in various embodiments. Furthermore, the TCOs do not necessarily correspond to a stoichiometric composition and can furthermore be p-doped or n-doped.

In various embodiments, the first electrode 112 can include a metal; for example Ag, Pt, Au, Mg, Al, Ba, In, Ag, Au, Mg, Ca, Sm or Li, and compounds, combinations or alloys of these materials.

In various embodiments, the first electrode 112 can be formed by a layer stack of a combination of a layer of a metal on a layer of a TCO, or vice versa. One example is a silver layer applied on an indium tin oxide layer (ITO) (Ag on ITO) or ITO-Ag-ITO multilayers.

In various embodiments, the first electrode 112 can provide one or a plurality of the following materials as an alternative or in addition to the above-mentioned materials: networks composed of metallic nanowires and nanoparticles, for example composed of Ag; networks composed of carbon nanotubes; graphene particles and graphene layers; networks composed of semiconducting nanowires.

Furthermore, the first electrode 112 can include electrically conductive polymers or transition metal oxides or transparent electrically conductive oxides.

In various embodiments, the first electrode 112 and the substrate 102 can be formed as translucent or transparent. In the case where the first electrode 112 is formed from a metal, the first electrode 112 can have for example a layer thickness of less than or equal to approximately 25 nm, for example a layer thickness of less than or equal to approximately 20 nm, for example a layer thickness of less than or equal to approximately 18 nm. Furthermore, the first electrode 112 can have for example a layer thickness of greater than or equal to approximately 10 nm, for example a layer thickness of greater than or equal to approximately 15 nm. In various embodiments, the first electrode 112 can have a layer thickness in a range of approximately 10 nm to approximately 25 nm, for example a layer thickness in a range of approximately 10 nm to approximately 18 nm, for example a layer thickness in a range of approximately 15 nm to approximately 18 nm.

Furthermore, for the case where the first electrode 112 is formed from a transparent conductive oxide (TCO), the first electrode 112 can have for example a layer thickness in a range of approximately 50 nm to approximately 500 nm, for example a layer thickness in a range of approximately 75 nm to approximately 250 nm, for example a layer thickness in a range of approximately 100 nm to approximately 150 nm.

Furthermore, for the case where the first electrode 112 is formed from, for example, a network composed of metallic nanowires, for example composed of Ag, which can be combined with conductive polymers, a network composed of carbon nanotubes which can be combined with conductive polymers, or from graphene layers and composites, the first electrode 112 can have for example a layer thickness in a range of approximately 1 nm to approximately 500 nm, for example a layer thickness in a range of approximately 10 nm to approximately 400 nm, for example a layer thickness in a range of approximately 40 nm to approximately 250 nm.

The first electrode 112 can be formed as an anode, that is to say as a hole-injecting electrode, or as a cathode, that is to say as an electron-injecting electrode.

The first electrode 112 can have a first electrical terminal, to which a first electrical potential (provided by an energy source (not illustrated), for example a current source or a voltage source) can be applied. Alternatively, the first electrical potential can be applied to the substrate 102 and then be fed indirectly to the first electrode 112 via said substrate. The first electrical potential can be, for example, the ground potential or some other predefined reference potential.

Furthermore, the electrically active region 110 of the light-emitting component 200 can have an organic electroluminescent layer structure 114, which is applied on or above the first electrode 112.

The organic electroluminescent layer structure 114 can contain one or a plurality of emitter layers 118, for example including fluorescent and/or phosphorescent emitters, and one or a plurality of hole-conducting layers 120 (also designated as hole transport layer(s) 120). In various embodiments, one or a plurality of electron-conducting layers 122 (also designated as electron transport layer(s) 122) can alternatively or additionally be provided.

Examples of emitter materials which can be used in the light-emitting component 200 in accordance with various embodiments for the emitter layer(s) 118 include organic or organometallic compounds such as derivatives of polyfluorene, polythiophene and polyphenylene (e.g. 2- or 2,5-substituted poly-p-phenylene vinylene) and metal complexes, for example iridium complexes such as blue phosphorescent FIrPic (bis(3,5-difluoro-2-(2-pyridyl)phenyl(2-carboxypyridyl) iridium III), green phosphorescent Ir(ppy)₃ (tris(2-phenylpyridine)iridium III), red phosphorescent Ru (dtb-bpy)₃*2(PF₆) (tris[4,4′-di-tert-butyl-(2,2′)-bipyridine]ruthenium(III) complex) and blue fluorescent DPAVBi (4,4-bis[4-(di-p-tolylamino)styryl]biphenyl), green fluorescent TTPA (9,10-bis[N,N-di(p-tolyl)amino]anthracene) and red fluorescent DCM2 (4-dicyanomethylene)-2-methyl-6-julolidyl-9-enyl-4H-pyran) as non-polymeric emitters. Such non-polymeric emitters can be deposited by means of thermal evaporation, for example. Furthermore, it is possible to use polymer emitters, which can be deposited, in particular, by means of a wet-chemical method such as spin coating, for example.

The emitter materials can be embedded in a matrix material in a suitable manner.

It should be pointed out that other suitable emitter materials are likewise provided in other embodiments.

The emitter materials of the emitter layer(s) 118 of the light-emitting component 200 can be selected for example such that the light-emitting component 200 emits white light. The emitter layer(s) 118 can include a plurality of emitter materials that emit in different colors (for example blue and yellow or blue, green and red); alternatively, the emitter layer(s) 118 can also be constructed from a plurality of partial layers, such as a blue fluorescent emitter layer 118 or blue phosphorescent emitter layer 118, a green phosphorescent emitter layer 118 and a red phosphorescent emitter layer 118. By mixing the different colors, the emission of light having a white color impression can result. Alternatively, provision can also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary and secondary radiation.

The organic electroluminescent layer structure 114 can generally include one or a plurality of electroluminescent layers. The one or the plurality of electroluminescent layers can include organic polymers, organic oligomers, organic monomers, organic small, non-polymeric molecules (“small molecules”) or a combination of these materials. By way of example, the organic electroluminescent layer structure 114 can include one or a plurality of electroluminescent layers embodied as a hole transport layer 120, so as to enable for example in the case of an OLED an effective hole injection into an electroluminescent layer or an electroluminescent region. Alternatively, in various embodiments, the organic electroluminescent layer structure 114 can include one or a plurality of functional layers embodied as an electron transport layer 122, so as to enable for example in an OLED an effective electron injection into an electroluminescent layer or an electroluminescent region. By way of example, tertiary amines, carbazo derivatives, conductive polyaniline or polyethylene dioxythiophene can be used as material for the hole transport layer 120. In various embodiments, the one or the plurality of electroluminescent layers can be embodied as an electroluminescent layer.

In various embodiments, the hole transport layer 120 can be applied, for example deposited, on or above the first electrode 112, and the emitter layer 118 can be applied, for example deposited, on or above the hole transport layer 120. In various embodiments, the electron transport layer 122 can be applied, for example deposited, on or above the emitter layer 118.

In various embodiments, the organic electroluminescent layer structure 114 (that is to say for example the sum of the thicknesses of hole transport layer(s) 120 and emitter layer(s) 118 and electron transport layer(s) 122) can have a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various embodiments, the organic electroluminescent layer structure 114 can have for example a stack of a plurality of organic light-emitting diodes (OLEDs) arranged directly one above another, wherein each OLED can have for example a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various embodiments, the organic electroluminescent layer structure 114 can have for example a stack of two, three or four OLEDs arranged directly one above another, in which case for example the organic electroluminescent layer structure 114 can have a layer thickness of a maximum of approximately 3 μm.

The light-emitting component 200 can optionally generally include further organic functional layers, for example arranged on or above the one or the plurality of emitter layers 118 or on or above the electron transport layer(s) 122, which serve to further improve the functionality and thus the efficiency of the light-emitting component 200.

The second electrode 116 (for example in the form of a second electrode layer 116) can be applied on or above the organic electroluminescent layer structure 114 or, if appropriate, on or above the one or the plurality of further organic functional layers.

In various embodiments, the second electrode 116 can include or be formed from the same materials as the first electrode 112, metals being particularly suitable in various embodiments.

In various embodiments, the second electrode 116 (for example for the case of a metallic second electrode 116) can have for example a layer thickness of less than or equal to approximately 50 nm, for example a layer thickness of less than or equal to approximately 45 nm, for example a layer thickness of less than or equal to approximately 40 nm, for example a layer thickness of less than or equal to approximately 35 nm, for example a layer thickness of less than or equal to approximately 30 nm, for example a layer thickness of less than or equal to approximately 25 nm, for example a layer thickness of less than or equal to approximately 20 nm, for example a layer thickness of less than or equal to approximately 15 nm, for example a layer thickness of less than or equal to approximately 10 nm.

The second electrode 116 can generally be formed in a similar manner to the first electrode 112, or differently than the latter. In various embodiments, the second electrode 116 can be formed from one or more of the materials and with the respective layer thickness, as described above in connection with the first electrode 112. In various embodiments, both the first electrode 112 and the second electrode 116 are formed as translucent or transparent. Consequently, the light-emitting component 200 illustrated in FIG. 1 can be designed as a top and bottom emitter (to put it another way as a transparent light-emitting component 200).

The second electrode 116 can be formed as an anode, that is to say as a hole-injecting electrode, or as a cathode, that is to say as an electron-injecting electrode.

The second electrode 116 can have a second electrical terminal, to which a second electrical potential (which is different than the first electrical potential), provided by the energy source, can be applied. The second electrical potential can have for example a value such that the difference with respect to the first electrical potential has a value in a range of approximately 1.5 V to approximately 20 V, for example a value in a range of approximately 2.5 V to approximately 15 V, for example a value in a range of approximately 3 V to approximately 12 V.

An encapsulation 124, for example in the form of a barrier thin-film layer/thin-film encapsulation 124, can optionally also be formed on or above the second electrode 116 and thus on or above the electrically active region 110.

In the context of this application, a “barrier thin-film layer” or a “barrier thin film” 124 can be understood to mean, for example, a layer or a layer structure which is suitable for forming a barrier against chemical impurities or atmospheric substances, in particular against water (moisture) and oxygen. In other words, the barrier thin-film layer 124 is formed in such a way that OLED-damaging substances such as water, oxygen or solvent cannot penetrate through it or at most very small proportions of said substances can penetrate through it.

In accordance with one configuration, the barrier thin-film layer 124 can be formed as an individual layer (to put it another way, as a single layer). In accordance with an alternative configuration, the barrier thin-film layer 124 can include a plurality of partial layers formed one on top of another. In other words, in accordance with one configuration, the barrier thin-film layer 124 can be formed as a layer stack. The barrier thin-film layer 124 or one or a plurality of partial layers of the barrier thin-film layer 124 can be formed for example by means of a suitable deposition method, e.g. by means of an atomic layer deposition (ALD) method in accordance with one configuration, e.g. a plasma enhanced atomic layer deposition (PEALD) method or a plasmaless atomic layer deposition (PLALD) method, or by means of a chemical vapor deposition (CVD) method in accordance with another configuration, e.g. a plasma enhanced chemical vapor deposition (PECVD) method or a plasmaless chemical vapor deposition (PLCVD) method, or by means of a molecular layer deposition (MLD), or alternatively by means of other suitable deposition methods.

By using an atomic layer deposition (ALD) method, it is possible for very thin layers to be deposited. In particular, layers having layer thicknesses in the atomic layer range can be deposited.

In accordance with one configuration, in the case of a barrier thin-film layer 124 having a plurality of partial layers, all the partial layers can be formed by means of an atomic layer deposition method. A layer sequence including only ALD layers can also be designated as a “nanolaminate”.

In accordance with an alternative configuration, in the case of a barrier thin-film layer 124 including a plurality of partial layers, one or a plurality of partial layers of the barrier thin-film layer 124 can be deposited by means of a different deposition method than an atomic layer deposition method, for example by means of a vapor deposition method.

In accordance with one configuration, the barrier thin-film layer 124 can have a layer thickness of approximately 0.1 nm (one atomic layer) to approximately 1000 nm, for example a layer thickness of approximately 10 nm to approximately 100 nm in accordance with one configuration, for example approximately 40 nm in accordance with one configuration.

In accordance with one configuration in which the barrier thin-film layer 124 includes a plurality of partial layers, all the partial layers can have the same layer thickness. In accordance with another configuration, the individual partial layers of the barrier thin-film layer 124 can have different layer thicknesses. In other words, at least one of the partial layers can have a different layer thickness than one or more other partial layers.

In accordance with one configuration, the barrier thin-film layer 124 or the individual partial layers of the barrier thin-film layer 124 can be formed as a translucent or transparent layer. In other words, the barrier thin-film layer 124 (or the individual partial layers of the barrier thin-film layer 124) can consist of a translucent or transparent material (or a material combination that is translucent or transparent).

In accordance with one configuration, the barrier thin-film layer 124 or (in the case of a layer stack having a plurality of partial layers) one or a plurality of the partial layers of the barrier thin-film layer 124 can include or consist of one of the following materials: aluminum oxide, zinc oxide, zirconium oxide, titanium oxide, hafnium oxide, tantalum oxide lanthanum oxide, silicon oxide, silicon nitride, silicon oxynitride, indium tin oxide, indium zinc oxide, aluminum-doped zinc oxide, and mixtures and alloys thereof. In various embodiments, the barrier thin-film layer 124 or (in the case of a layer stack having a plurality of partial layers) one or a plurality of the partial layers of the barrier thin-film layer 124 can include one or a plurality of high refractive index materials, to put it another way one or a plurality of materials having a high refractive index, for example having a refractive index of at least 2.

In various embodiments, on or above the encapsulation 124, it is possible to provide an adhesive and/or a protective lacquer 126, by means of which, for example, a cover 128 (for example a glass cover 128) is fixed, for example adhesively bonded, on the encapsulation 124. In various embodiments, the optically translucent layer composed of adhesive and/or protective lacquer 126 can have a layer thickness of greater than 1 μm, for example a layer thickness of several μm. In various embodiments, the adhesive can include or be a lamination adhesive. It should be pointed out that a cover 128 is not absolutely necessary, for example if a protective lacquer 126 is provided.

In various embodiments, light-scattering particles can also be embedded into the layer of the adhesive (also designated as adhesive layer), which particles can lead to a further improvement in the color angle distortion and the coupling-out efficiency. In various embodiments, the light-scattering particles provided can be dielectric scattering particles, for example, such as metal oxides, for example, such as e.g. silicon oxide (SiO₂), zinc oxide (ZnO), zirconium oxide (ZrO₂), indium tin oxide (ITO) or indium zinc oxide (IZO), gallium oxide (Ga₂Oₐ), aluminum oxide, or titanium oxide. Other particles may also be suitable provided that they have a refractive index that is different than the effective refractive index of the matrix of the translucent layer structure, for example air bubbles, acrylate, or hollow glass beads. Furthermore, by way of example, metallic nanoparticles, metals such as gold, silver, iron nanoparticles, or the like can be provided as light-scattering particles.

In various embodiments, between the second electrode 116 and the layer composed of adhesive and/or protective lacquer 126 an electrically insulating layer (not shown) can also be applied, for example SiN, for example having a layer thickness in a range of approximately 300 nm to approximately 1.5 μm, for example having a layer thickness in a range of approximately 500 nm to approximately 1 μm, in order to protect electrically unstable materials, during a wet-chemical process for example.

In various embodiments, the adhesive can be designed in such a way that it itself has a refractive index which is less than the refractive index of the cover 128. Such an adhesive can be, for example, a low refractive index adhesive such as, for example, an acrylate having a refractive index of approximately 1.3. Furthermore, a plurality of different adhesives which form an adhesive layer sequence can be provided.

Furthermore, it should be pointed out that, in various embodiments, an adhesive 126 can also be completely dispensed with, for example in embodiments in which the cover 128, for example composed of glass, is applied to the encapsulation 124 by means of plasma spraying, for example.

Furthermore, in various embodiments, one or a plurality of antireflective layers (for example combined with the encapsulation 124, for example the thin-film encapsulation 124) can additionally be provided in the light-emitting component 200.

It should be pointed out that for the above-described embodiments in which the radiation-absorbing material 106 is provided only between the substrate 102 and the electrically active region 110, more precisely for example between the substrate 102 and the first electrode 112, the second electrode 116 can be designed as specularly reflective.

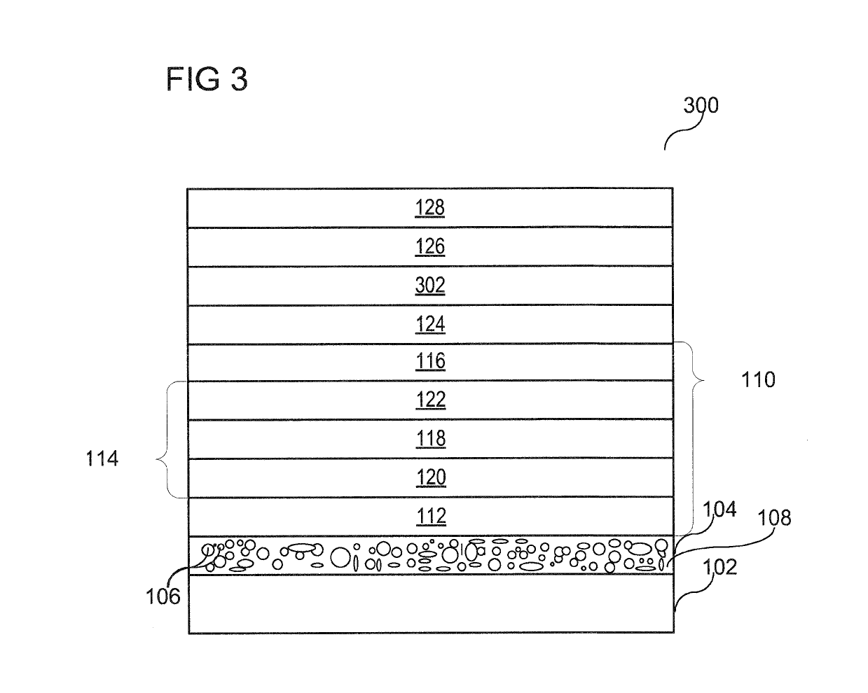

FIG. 3 shows a cross-sectional view of a light-emitting component 300 in accordance with various embodiments, for example likewise implemented as an organic light-emitting diode 300.

The organic light-emitting diode 300 in accordance with FIG. 3 is identical in many aspects to the organic light-emitting diode 200 in accordance with FIG. 2, for which reason only the differences between the organic light-emitting diode 300 in accordance with FIG. 3 and the organic light-emitting diode 200 in accordance with FIG. 2 are explained in greater detail below; with regard to the remaining elements of the organic light-emitting diode 300 in accordance with FIG. 3, reference is made to the above explanations concerning the organic light-emitting diode 200 in accordance with FIG. 2.

In contrast to the organic light-emitting diode 200 in accordance with FIG. 2, in various embodiments, as shown in FIG. 3, additional radiation-absorbing material 302 is provided, for example arranged between the encapsulation 124 and the adhesive and/or protective lacquer 126. The additional radiation-absorbing material 302 can be designed identically to the material 106 described above and can be produced and applied in the same way. The radiation-absorbing material 302 can be designed to absorb radiation having wavelengths of a maximum of 600 nm; for example, it can be designed to absorb UV radiation and/or blue light. In various embodiments, the radiation-absorbing material 302 can be embedded into a matrix of a carrier material. Consequently, illustratively, the additional radiation-absorbing material 302 can be applied for example in the form of a material layer on or above the encapsulation 124, and the adhesive and/or protective lacquer 126 can be applied on or above the material layer, generally above the additional radiation-absorbing material 302.

It should be pointed out that, in various embodiments, however, the radiation-absorbing materials 106, 302 can also be different in the different regions of the OLED, but they always have the desired radiation-absorbing property.

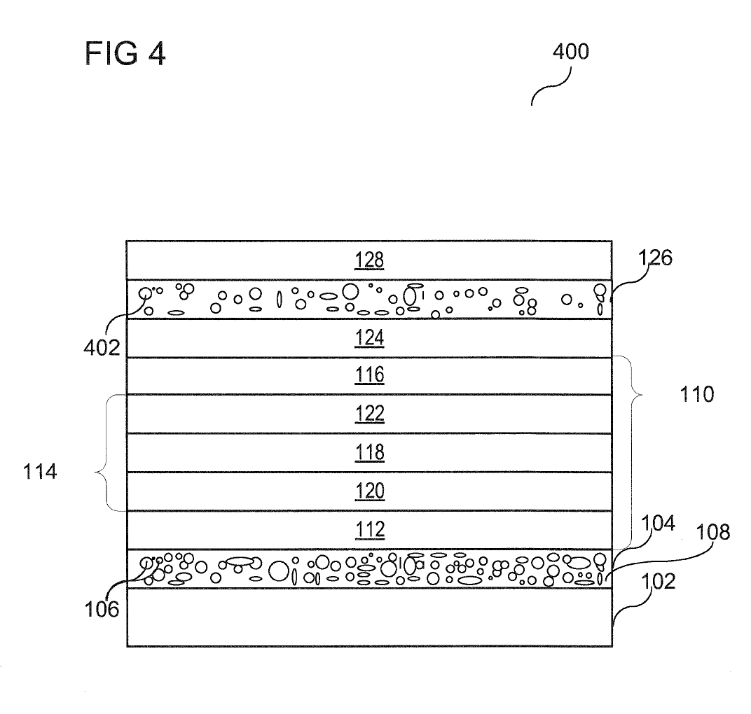

FIG. 4 shows a cross-sectional view of a light-emitting component 400 in accordance with various embodiments, for example likewise implemented as an organic light-emitting diode 400.

The organic light-emitting diode 400 in accordance with FIG. 4 is identical in many aspects to the organic light-emitting diode 200 in accordance with FIG. 2, for which reason only the differences between the organic light-emitting diode 400 in accordance with FIG. 4 and the organic light-emitting diode 200 in accordance with FIG. 2 are explained in greater detail below; with regard to the remaining elements of the organic light-emitting diode 400 in accordance with FIG. 4, reference is made to the above explanations concerning the organic light-emitting diode 200 in accordance with FIG. 2.

In contrast to the organic light-emitting diode 200 in accordance with FIG. 2, in various embodiments, provision is made, as shown in FIG. 4, for additional radiation-absorbing material 402 to be added to, for example admixed with, the adhesive and/or protective lacquer 126. The additional radiation-absorbing material 402 can be designed identically to the material 106 such as has been described above.

It should be pointed out that, in various embodiments, however, the radiation-absorbing materials 106, 402 can also be different in the different regions of the OLED, but they always have the desired radiation-absorbing property.

In various embodiments, it can be provided that the organic light-emitting diodes 300, 400 in accordance with FIG. 3 and FIG. 4 are configured as transparent organic light-emitting diodes.

Furthermore, it can be provided that the radiation-absorbing materials are designed and arranged in such a way that, in each case in the region in which they have been arranged, they provide a filter function having a steep edge having an upper limit of the transmission spectrum of approximately 85% absorption and having a lower limit of approximately 2% absorption. In various embodiments, the edge steepness can be in a range of approximately 20 nm.

Consequently, in various embodiments, provision is made for introducing specific radiation-absorbing materials, for example in the form of specific radiation-absorbing layers, for example specific UV-blocking layers, at various locations within an organic light-emitting diode. Such materials can be arranged for example in the form of an intermediate layer between the substrate (for example a glass substrate) and the first (for example transparent) electrode, for example in the case of an organic light-emitting diodes that emit on the substrate side.

In the case of a transparent organic light-emitting diodes, in various embodiments, provision can be made for providing such a radiation-absorbing material also on the other side of the electrically active region and thus for example on or above the encapsulation (for example between the encapsulation and the cover), in addition to the radiation-absorbing material provided between the substrate and the first electrode. In this way, the organic light-emitting diode, for example the organic functional layer stack, would be protected against radiation having a predefined wavelength, for example against UV radiation, from both sides.

In various embodiments, the introduced material, for example in the form of a material layer, can be applied wet-chemically and also by means of a deposition method, for example by means of a vacuum deposition method.

In the case of wet-chemical processes, the UV-absorbing pigments, to put it another way the UV-absorbing material (e.g. inorganic: TiO₂ or zinc oxide pigments, organic: camphor, salicylic acid, cinnamic acid), can be embedded into a transparent matrix and applied as thin layers (layer thickness of a few to several μm) to the substrate or the thin-film encapsulation. In said transparent matrix, it is also possible additionally to introduce light-scattering particles (for example TiO₂, Al₂O₃, pores, SiO), as described above, in order to scatter the visible light. In addition to the UV protection, the light coupling-out of the organic light-emitting diode is also improved as a result. For the case where the UV-blocking layer also contributes to the improvement in the light coupling-out, the refractive index of said layer should be taken into consideration. It should be at least equal to or greater than the refractive index of the substrate, for example of the glass substrate (n˜1.5). In order to be able to couple out even more light, the refractive index should be greater than or equal to the refractive index of the organic layers (usually n˜1.8). The introduced scattering particles should have a difference in refractive index with respect to the matrix in order to bring about an effective light scattering.

By means of vacuum deposition (for example PECVD or ALD) it is possible, for example, to apply a thin UV-blocking layer (layer thicknesses of <1 μm) to the substrate or the encapsulation. Here, the particular advantage is that the layer lies in the inner region of the OLED and is thereby protected against physical destruction, since otherwise it can be scraped away very easily (e.g. as a result of the cleaning of the OLED). In various embodiments, materials provided in this case include, for example, TiO₂, ZnO₂ or SiN. These materials absorb the light for example in the UV range. It is likewise possible to produce a mirror for the UV light over multilayers of thin-film layers.

In various embodiments, the organic light-emitting diode 300 in accordance with FIG. 3 and the organic light-emitting diode in accordance with FIG. 4 can also be provided in combination with one another.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. A method for producing an optoelectronic component, the method comprising:
applying a planarization medium to a surface of a substrate, wherein the planarization medium comprises a material which absorbs electromagnetic radiation having wavelengths of a maximum of 600 nm;
applying a first electrode on or above the material;
forming an organic functional layer structure on or above the first electrode; and
forming a second electrode on or above the organic functional layer structure.

2. The method as claimed in claim 1,
wherein the planarization medium is applied with a thickness such that a percentage of the light is absorbed in a range of approximately 85% to approximately 99%.

3. The method as claimed in claim 1,
wherein the material which absorbs radiation having wavelengths of a maximum of 600 nm is admixed with a carrier material, such that the planarization medium is formed; and
wherein, after admixing the material, the planarization medium is applied to the surface of the substrate.

4. The method as claimed in claim 1, wherein the planarization medium is applied to the surface of the substrate by means of one of: spin coating, blade coating, printing, spraying, spreading, rolling, drawing, wiping, dipping, flooding, or slot casting.

5. The method as claimed in claim 1,
wherein the planarization medium is a liquid; and
wherein, after applying the planarization medium, the planarization medium is cured.

6. The method as claimed in claim 5, wherein curing comprises at least one of:
outdiffusion of a solvent contained in the planarization medium;
irradiation of the planarization medium with electromagnetic radiation; and/or
heating of the planarization medium; and/or
polymerization by air moisture; and/or
reaction of two constituents of the planarization medium.

7. The method as claimed in claim 1, wherein the material is designed in such a way that it absorbs radiation having wavelengths of a maximum of 400 nm.

8. An optoelectronic component, comprising:
a substrate;
a planarization medium applied on a surface of the substrate, wherein the planarization medium comprises a material which absorbs radiation having wavelengths of a maximum of 600 nm;
a first electrode on or above the material;
an organic functional layer structure on or above the first electrode; and
a second electrode on or above the organic functional layer structure.

9. The optoelectronic component as claimed in claim 8,
wherein the planarization medium and/or the material have/has a thickness such that a percentage of the light is absorbed in a range of approximately 85% to approximately 99%.

10. The optoelectronic component as claimed in claim 8,
wherein the material which absorbs radiation having wavelengths of a maximum of 600 nm is embedded in a matrix material.

11. The optoelectronic component as claimed in claim 8,
wherein the planarization medium comprises a polymer to which the material which absorbs radiation having wavelengths of a maximum of 600 nm is bonded as molecule radical.

12. The optoelectronic component as claimed in claim 8,
wherein the material is designed in such a way that it absorbs radiation having wavelengths of a maximum of 400 nm.

13. The optoelectronic component as claimed in claim 8,
wherein the optoelectronic component comprises a light-emitting component and/or a solar cell.

14. The optoelectronic component as claimed in claim 8,
wherein the planarization medium has a roughness of a maximum of 0.25 μm.
